(19) United States
(12) Patent Application Publication
(10) Pub. No.: US 2026/0211470 A1
(43) Pub. Date: Jul. 23, 2026

(54) ANTI-REFLOW DEVICES AND METHODS OF USE THEREOF

(71) Applicant: Quanta Computer Inc., Taoyuan City (TW)

(72) Inventors: Yaw-Tzorng TSORNG, Taoyuan City (TW); Tung-Hsien WU, Taoyuan City (TW); Chin-Ho KUO, Taoyuan City (TW); Wei-Lun GAO, Taoyuan City (TW)

(21) Appl. No.: 19/033,147

(22) Filed: Jan. 21, 2025

(51) Int. Cl. G06F 1/20; G06F 1/18; H05K 7/20

(52) U.S. Cl. CPC G06F 1/20; G06F 1/181; H05K 7/20145

(57) ABSTRACT

An anti-reflow device for preventing air reflow from one or more fan modules includes a first wall, a second wall, and a screen. The second wall is positioned opposite and generally parallel to the first wall such that an opening is defined between the first wall and the second wall. The screen is positioned within the opening defined between the first wall and the second wall and is movable to adjust a size of the opening.

### FIELD OF THE INVENTION

The present invention relates generally to computing devices with improved routing of cables, and more specifically, to anti-reflow devices allowing for proper routing of cables while preventing air reflow from fan modules

### BACKGROUND OF THE INVENTION

Many computing devices, such as servers, have a large number of cables connecting various components. These components will often include a number of fan modules that are operated to cause air to flow in a desired direction to aid in cooling the computing device during operation. Due to the arrangement of the computing device, the cables will often extend through gaps between different fan modules. While these gaps allow for the cables to routed properly, they also provide an opening through which air reflow can occur, which reduces the effectiveness of the fan modules and negatively affects the performance of the computing device. Thus, new air reflow devices needed for allowing the proper routing of cables and preventing air reflow from fan modules.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

In a first implementation, the present disclosure is directed to a computing device comprising one or more fan modules and an anti-reflow device for preventing air reflow from the one or more fan modules. The anti-reflow device includes a first wall, a second wall positioned opposite and generally parallel to the first wall such that an opening is defined between the first wall and the second wall, and a screen positioned within the opening defined between the first wall and the second wall. The screen is movable to adjust a size of the opening.

In some aspects of the first implementation, the screen has a first end and a second opposing end. The first end is coupled adjacent to a first end of the first wall and a first end of the second wall. The second end is movable relative to an opposing second end of the first wall and an opposing second end of the second wall.

In some aspects of the first implementation, the first end of the screen is coupled to (i) the first end of the first wall, (ii) the first end of the second wall, (iii) a top plate extending between the first end of the first wall and the first end of the second wall, (iv) or any combination of (i)-(iii).

In some aspects of the first implementation, the second end of the screen moves relative to the second end of the first wall and the second end of the second wall to adjust the size of the opening.

In some aspects of the first implementation, the screen is formed from a plurality of screen members pivotally coupled together. Each of the plurality of screen members extends between the first wall and the second wall.

In some aspects of the first implementation, the plurality of screen members are configured to fold onto each other as the screen is moved such that a size of the screen decreases as the size of the opening increases.

In some aspects of the first implementation, the plurality of screen members are pivotally coupled such that a folding direction of two adjacent screen members alternates for every adjacent pair of the plurality of screen members.

In some aspects of the first implementation, the plurality of screen members includes a first screen member, a second screen member pivotally coupled at one end to the first screen member, and a third screen member pivotally coupled to an opposing end of the second screen member.

In some aspects of the first implementation, a first folding direction of the first screen member and the second screen member extends from the pivotal coupling between the first screen member and the second screen member in a first direction, and wherein a second folding direction of the second screen member and the third screen member extends from the pivotal coupling between the second screen member and the third screen member in a second direction that is perpendicular to and opposite the first direction.

In some aspects of the first implementation, the anti-reflow device further includes a rib that presses against the first screen member and the second screen member to bias the first screen member and the second screen member toward the first folding direction.

In some aspects of the first implementation, each pair of screen members of the plurality of screen members is pivotally coupled via at least one hinge that allows each of the pair of screen members to pivot in one circular direction but not in an opposite circular direction.

In some aspects of the first implementation, the at least one hinge that pivotally couples each pair of screen members includes at least one stopping flange that prevents each of the pair of screen members from pivoting in the opposite circular direction.

In some aspects of the first implementation, an orientation of the at least one hinge that couples each pair of screen members alternates for each adjacent pair of screen members.

In some aspects of the first implementation, the screen includes a latch that mates with one or both of the first wall and the second wall to lock the screen and the size of the opening.

In some aspects of the first implementation, the first wall includes a plurality of slots defined therein extending along a length of the first wall, and wherein the latch includes a pin extending from the screen toward the first wall, the pin being selectively insertable into one of the plurality of slots to lock the screen and the size of the opening.

In some aspects of the first implementation, the first wall includes at least one detent extending into at least one slot of the plurality of slots, the detent of the at least one slot resisting movement of the pin out of the at least one slot when the pin is inserted into the at least one slot.

In some aspects of the first implementation, the first wall includes a channel defined therein that is continuous with each of the plurality of slots, and the pin is movable only within the channel, into the plurality of slots, and out of the plurality of slots.

In some aspects of the first implementation, the one or more fan modules are coupled to a fan wall housing, and a portion of the fan wall housing is positioned adjacent to the screen opposite the first wall of the anti-reflow device such that movement of the pin of the anti-reflow device is restricted by the first wall of the anti-reflow device and the portion of the fan wall.

In a second implementation, the present disclosure is directed to a computing device that comprises one or more electronic components, a fan wall, one or more cables, and an anti-reflow device. The fan wall includes at least a first fan module, a second fan module, and an opening defined between the first fan module and the second fan module. The anti-reflow device is mounted at least partially in the opening defined between the first fan module and the second fan module. The anti-reflow device includes a first wall, a second wall, and a screen. The second wall is positioned opposite and generally parallel to the first wall such that an opening is defined between the first wall and the second wall. The opening of the anti-reflow device overlaps at least partially with the opening of the fan wall. The screen is positioned within the opening defined between the first wall and the second wall and is movable relative to the first wall and the second wall. The one or more cables extend through the opening in the fan wall and the opening in the anti-reflow device. The screen is movable to adjust a size of the opening of the anti-reflow device to accommodate a size of the one or more cables extending therethrough.

In some aspects of the second implementation, the screen is formed from a plurality of pivotally coupled screen members configured to fold onto each other as the screen is moved to decrease a size of the opening of the anti-reflow device. A folding direction of each pair of screen members alternates for every adjacent pair of screen members.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 illustrates an anti-reflow device with a screen, according to certain aspects of the present disclosure.

FIG. 2 illustrates a pin of the anti-reflow device being inserted into a slot of the anti-reflow device, according to certain aspects of the present disclosure.

FIG. 3A illustrates a first type of screen member forming the screen of the anti-reflow device, according to certain aspects of the present disclosure.

FIG. 3B illustrates a second type of screen member forming the screen of the anti-reflow device, according to certain aspects of the present disclosure.

FIG. 4 illustrates a hinge that pivotally couples screen members of the screen of the anti-reflow device, according to certain aspects of the present disclosure.

FIG. 5A illustrates a pair of screen members in a fully or substantially unfolded position, according to certain aspects of the present disclosure.

FIG. 5B illustrates the pair of screen members in a fully or substantially folded position, according to certain aspects of the present disclosure.

FIG. 6 illustrates the folding directions of the screen members of the screen of the anti-reflow device, according to certain aspects of the present disclosure.

FIG. 7 illustrates a connection point of a top plate of the anti-reflow device, according to certain aspects of the present disclosure.

FIG. 8A illustrates the anti-reflow device when the screen is in a first position, according to certain aspects of the present disclosure.

FIG. 8B illustrates the anti-reflow device when the screen is in a second position, according to certain aspects of the present disclosure.

FIG. 9A illustrates a biasing tab of the anti-reflow device, according to certain aspects of the present disclosure.

FIG. 9B illustrates the biasing tab biasing a pair of screen members toward a specific folding direction, according to certain aspects of the present disclosure.

FIG. 10A illustrates a computing device without the anti-reflow device installed, according to certain aspects of the present disclosure.

FIG. 10B illustrates the computing device with the screen of the anti-reflow device in the fully unfolded position, according to certain aspects of the present disclosure.

FIG. 10C illustrates a computing device with the screen of the anti-reflow device in the fully unfolded position and a pair of cables extending through an opening of the anti-reflow device, according to certain aspects of the present disclosure.

FIG. 10D illustrates a computing device with the screen of the anti-reflow device in a more folded position and the pair of cables extending through an opening of the anti-reflow device, according to certain aspects of the present disclosure.

FIG. 11A illustrates the anti-reflow device installed in the computing device and in close proximity to a fan wall housing of a fan wall of the computing device, according to certain aspects of the present disclosure.

FIG. 11B illustrates pins of the anti-reflow device movable within slots defined by the anti-reflow device and within a channel partially defined by the fan wall housing, according to certain aspects of the present disclosure.

FIG. 12 illustrates an additional implementation of the anti-reflow device where pins of the anti-reflow device are movable within slots and a channel defined by the anti-reflow device, according to certain aspects of the present disclosure.

### DETAILED DESCRIPTION

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

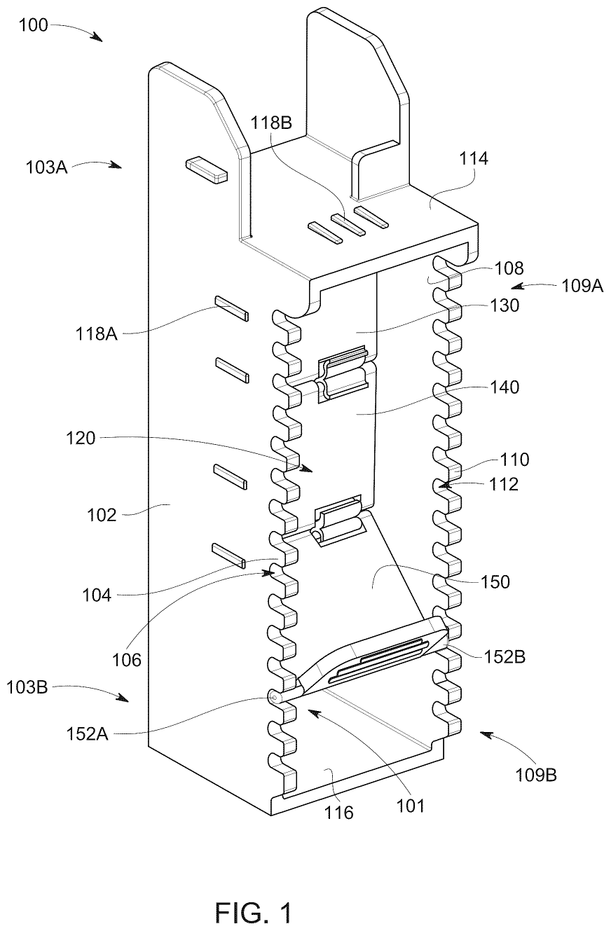

FIG. 1 illustrates an anti-reflow device 100 for use in a computing device. The anti-reflow device is formed from a first wall 102, a second wall 108, a top plate 114, a bottom plate 116, and a screen 120. The first wall 102 and the second wall 108 are generally parallel to each other. The top plate 114 and the bottom plate 116 are generally parallel to each other, and perpendicular to the first wall 102 and the second wall 108. The top plate 114 is coupled to a first end 103A of the first wall 102 and a first end 109A of the second wall 108. The bottom plate 116 is coupled to an opposing second end 103B of the first wall 102 and an opposing second end 109B of the second wall 108. An opening 101 is defined between the first wall 102, the second wall 108, the top plate 114, and the bottom plate 116. The screen 120 is positioned at least partially within the opening 101. The first end of the screen 120 is coupled adjacent to the first end 103A of the first wall 102, and the first end 109A of the second wall 108, while the opposing second end of the screen 120 is movable relative to the seconds end 103B of the first wall 102, the second end 109B of the second wall 108, and the bottom plate 116. The screen 120 may be coupled to any combination of the first wall 102, the second wall 108, and the top plate 114. For example, in some implementations, the screen 120 is coupled only to the top plate 114.

The screen 120 is formed from a plurality of individual screen members that are pivotally coupled to each other. In the illustrated implementation, the plurality of screen members includes a first screen member 130, a second screen member 140 pivotally coupled at one end to the first screen member 130, and a third screen member 150 pivotally coupled to the opposite end of the second screen member 140. The first screen member 130 will generally be pivotally coupled to whichever portion of the anti-reflow device 100 the screen 120 is coupled. For example, if the screen 120 is coupled to the top plate 114, then the first screen member 130 will be pivotally coupled to the top plate 114. The first screen member 130 may be referred to as an initial screen member (e.g., a screen member that is coupled to some other portion of the anti-reflow device 100 that is not another screen member), while the second screen member 140 and the third screen member 150 may be referred to as subsequent screen members (e.g., a screen member that is not coupled to any structure other than another screen member). The third screen member 150 may also be referred to as a final screen member (e.g., a screen member that is coupled to only one other screen member and is not coupled to any other structure).

In general, the screen 120 will include a plurality of screen members that includes an initial screen member and one or more subsequent screen members. The initial screen member will be coupled to (i) any combination of the first wall 102, the second wall 108, and the top plate 114 and (ii) one of the subsequent screen members. Each of the one or more subsequent screen members will be coupled to at least one of the other screen members, and will not be coupled to any structure other than one of the other screen members. Thus, a subsequent screen member may be coupled to two other screen members (e.g., the second screen member 120), or may also be a final screen member that is coupled to only one other screen member (e.g., the third screen member 150).

In implementations where the screen 120 includes only two screen members, the one or more subsequent screen members will include only one subsequent screen member that is also the final screen member (because it is not coupled to any structure other than another screen member and is coupled to only one other screen member). In implementations where the screen 120 includes three or more screen members, the one or more subsequent screen members will include at least one subsequent screen member that is not a final screen member (because it is not coupled to any structure other than another screen member, and is coupled to multiple other screen members), and at least one subsequent screen member that is also the final screen member (because it is not coupled to any structure other than another screen member and is coupled to only one other screen member).

By moving the screen 120 (and thus the plurality of screen members), the size of the opening 101 can be adjusted. As discussed in more detail herein, the size of the opening 101 can be adjusted by moving the second end of the screen 120 (e.g., the third screen member 150) relative to the second end 103B of the first wall 102 and the second end 109B of the second wall 108, to accommodate cables in the computing device that extend through the opening 101. By extending the screen 120 to a longer length (so that the screen members 130-150 are unfolded), the size of the opening 101 is decreased, and by retracting the screen 120 to a shorter length (so that the screen members 130-150 fold onto themselves), the size of the opening 101 is increased. By decreasing the size of the opening 101 as much as possible while allowing the cables to pass through, air flow in an undesired direction within the computing device can be prevented. The screen 120 generally extends the entire distance between the first wall 102 and the second wall 108 for any position of the screen 120.

The first wall 102 includes a plurality of teeth 104 projecting from the edge of the first wall 102 that define a plurality of slots 106. Similarly, the second wall 108 includes a plurality of teeth 110 projecting from the edge of the second wall 108 that define a plurality of slots 112. In the illustrated implementation, the teeth 104 and the slots 106 extend the entire length of the edge of the first wall 102, from the first end 103A to the second end 103B. Similarly, the teeth 110 and the slots 112 extend the entire length of the edge of the second wall 108, from the first end 109A to the second end 109B.

The screen 120 includes two pins 152A and 152B extending from either side of the third screen member 150 that are configured to mate with the slots 106 of the first wall 102 and the slots 112 of the second wall 108. Pin 152A extends toward the first wall 102 and can be selectively inserted into one of the slots 106, between two of the teeth 104. Pin 152B extends toward the second wall 108 and can be selectively inserted into one of the slots 112, between two of the teeth 110. The pins 152A and 152B thus act as a latch that is used to lock the screen 120 in place, which in turn locks the size of the opening 101. The teeth 104, 110 and the slots 106, 112 thus generally define the various different positions of the screen 120 when the anti-reflow device 100 is in use.

While FIG. 1 shows the teeth 104 and the slots 106 extending the entire length of the first wall 102, other implementations of the anti-reflow device 100 may include any number of teeth 104 defining any number of slots 106. Similarly, while the teeth 110 and the slots 112 are shown as extending the entire length of the second wall 108, other implementations of the anti-reflow device 100 may include any number of teeth 104, 110 and any number of slots 106, 112, defining any number of possible positions of the screen 120 during use of the anti-reflow device 100.

FIG. 1 also shows a variety of different protrusions that extend from various different surfaces of the anti-reflow device. One or more protrusions 118A extend from the first wall 102, one or more protrusions 118B extend from the top plate 115, and one or more protrusions (not visible in FIG. 1) extend from second wall 108. In implementations that include any of these protrusions, the protrusions can be used to lock the anti-reflow device 100 to any other structure, such as the housing of a computing device, a fan wall housing of a fan wall, another component, etc.

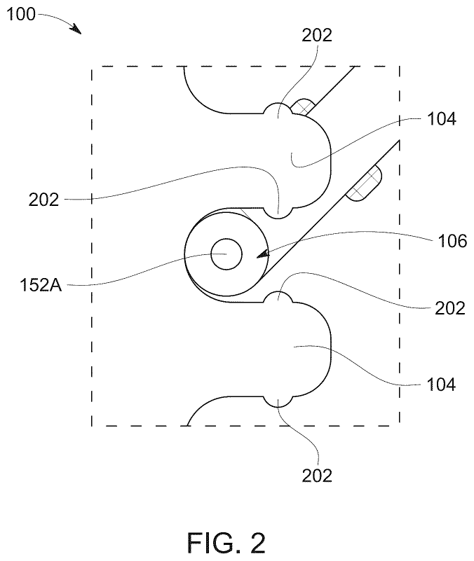

FIG. 2 shows a zoomed-in view of the pin 152A inserted into one of the slots 106 of the first wall 102. As shown, each of the teeth 104 includes a pair of detents 202 that extend into the adjacent slots 106. Thus, each of the slots 106 will have a pair of detents 202 (one detent 202 from each adjacent one of the teeth 104) that extend therein. The distance between two detents 202 within one of the slots 106 is smaller than the diameter of the pin 152A. Thus, the detents 202 resist movement of the pin 152A out of the slot 106, and aid in locking the screen 120 in place.

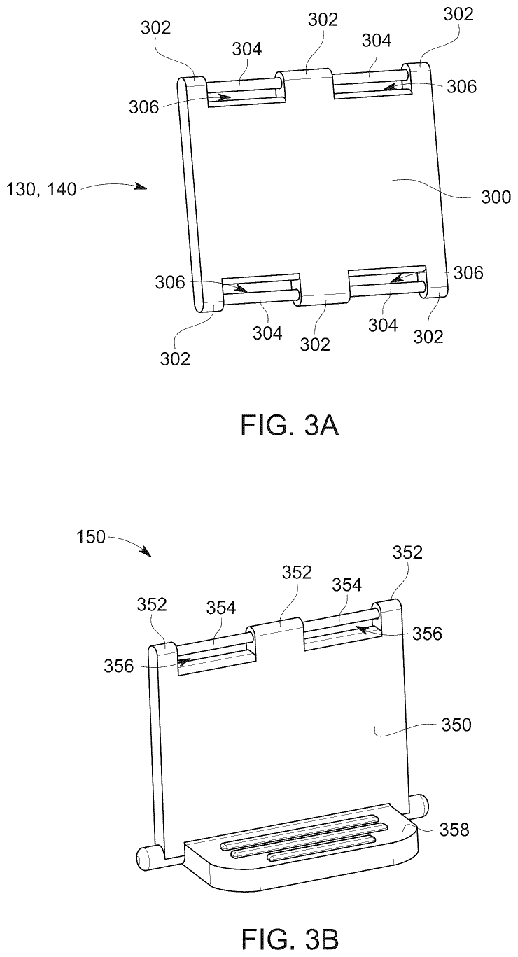

FIG. 3A shows a perspective view of the first screen member 130 and the second screen member 140, which generally have the same design. As shown, the screen member 130, 140 includes a body 300 with a set of tabs 302 extending from opposing edges of the body 300. The body 300 has a generally square shape. The screen member 130, 140 further includes rods 304 formed along the opposing edges. In the illustrated implementation, the rods 304 are formed in pairs along each edge with each rod 304 positioned between two of the tabs 302. However, other implementations may include only a single rod 304 along either of the edges (which may include only two tabs 302), or three or more rods 304 along either of the edges (which may include four or more tabs 302). Gaps 306 are defined between each of the rods 304 and the body 300. The rods 304 may be integrally formed with the body 300 and the tabs 302, or may be formed separately and then coupled to the tabs 302.

FIG. 3B shows the third screen member 150. The third screen member 150 has a body 350 with a set of tabs 352 extending along only one edge of the body 350. The body 350 has a generally square shape. The third screen member 150 further includes rods 354 formed along only the single edge of the body 350, with small gaps 356 defined between each of the rods 354 and the body 350. In the illustrated implementation, the rods 354 are formed in a pair of rods along the single edge with each rod 354 positioned between two of the tabs 352. However, other implementations may include only a single rod 354 along the edge (which may include only two tabs 352), or three or more rods 354 along the edge (which may include four or more tabs 302). Small gaps 356 are defined between each of the rods 354 and the body 350. The rods 354 may be integrally formed with the body 350 and the tabs 352, or may be formed separately and then coupled to the tabs 352. On the opposing edge of the body 350, instead of additional rods 354, the third screen member 150 includes an outwardly-extending tab 358. In the illustrated implementation, the tab 358 extends at roughly a right angle from the body 350, but may extend at any angle in other implementations.

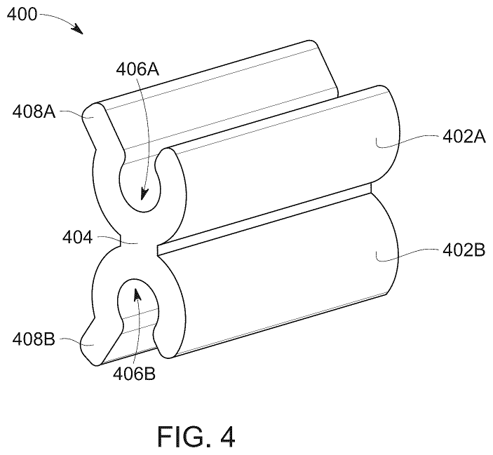

FIG. 4 shows a hinge 400 that is used to pivotally couple the screen members together. The hinge 400 includes two separate receiving portions 402A and 402B that are connected by a central portion 404. The receiving portions 402A and 402B define respective channels 406A and 406B that are sized to receive the rods 304 of the first screen member 130 and the second screen member 140, and the rods 354 of the screen member 450. The channels 406A and 406B are large enough to allow the rods 304 and 354 to rotate therein. The receiving portions 402A and 402B are wide enough so that the channels 406A, 406B have has a length approximately equal to the length of the rods 304 and 354. In some implementations, the receiving portions 402A and 402B are formed from a resilient material and have an opening that is slightly narrower than the diameter of the rods 304 and 354. This allows the hinges 400 to snap onto the rods 304 and 354, and prevents the screen members from being separated from each other via any inadvertent force experienced by the screen members 130-150 or the hinges 400 during use. The hinge 400 also includes a stopping flange 408A extending from one side of the receiving portion 402A, and a stopping flange 408B extending from one side of the receiving portion 402B. The stopping flanges 408A and 408B prevent the screen members from folding toward the stopping flanges 408A, 408B.

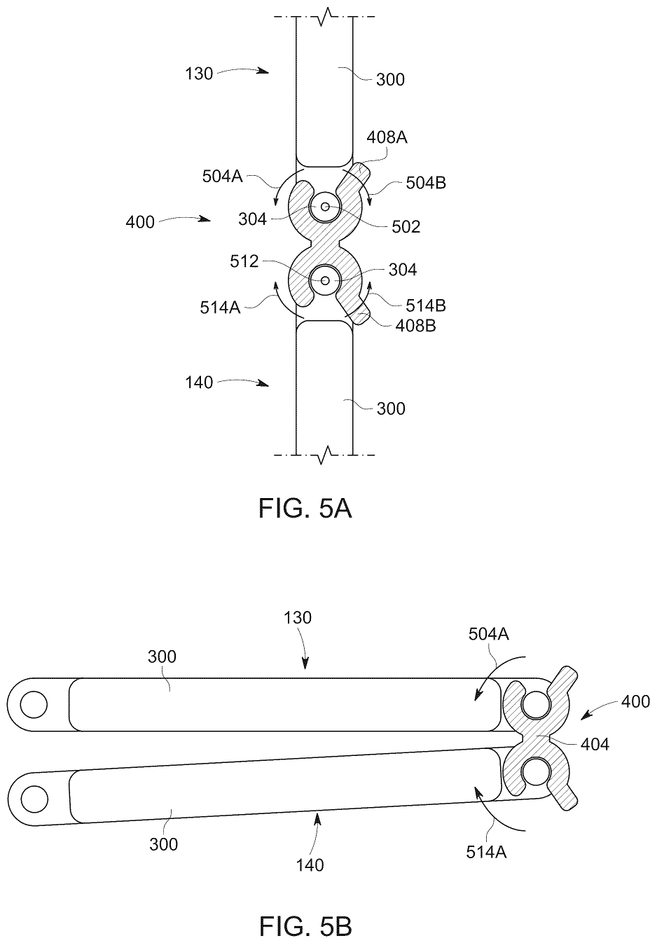

FIG. 5A is a side view of the first screen member 130 and the second screen member 140 when they fully or substantially folded. The first screen member 130 and the second screen member 140 are connected via the hinge 400 and unfolded so that the first screen member 130 and the second screen member 140 are aligned end-to-end (e.g., a single axis cannot extend normal to the body 300 of both screen members 130 and 140). As shown, a lower one of the rods 304 of the first screen member 130 is disposed in the channel 406A of the receiving portion 402A, and an upper one of the rods 304 of the second screen member 140 is disposed in the channel 406B of the receiving portion 402B. The first screen member 130 can thus pivot about an axis 502 that is coaxial with the rod 304 of the first screen member 130 and extends into and out of the plane of the figure. Similarly, the second screen member 140 can pivot about an axis 512 that is coaxial with the rod 304 of the second screen member 140 (and generally parallel to the axis 502 about which the first screen member 130 pivots).

However, the stopping flanges 408A and 408B restrict the directions in which the screen members 130 and 140 can pivot, and thus the folding direction of the pair of screen members 130 and 140. The first screen member 130 is able to rotate in a circular direction 504A about the axis 502 away from the stopping flange 508A, but is not able to rotate in the opposite circular direction 504B about the axis 502 toward the stopping flange 408A. The stopping flange 408A is longer than the height of the gap 406 that is adjacent to the stopping flange 508A (between the rod 304 and the body 300), and thus contact between the stopping flange 408A and the body 300 of the first screen member 130 will prevent rotation in the circular direction 504B. Similarly, the second screen member 140 is able to rotate in a circular direction 514A about the axis 512 away from the stopping flange 408B, but is not able to rotate in the opposite circular direction 514B about the axis 512 toward the stopping flange 408B. The stopping flange 408B is longer than the height of the gap 306 that is adjacent to the stopping flange 408B (between the rod 304 and the body 300), and thus contact between the stopping flange 408B and the body 300 of the second screen member 140 will prevent rotation in the circular direction 514B. Thus, the folding direction of a pair of screen members can be set by orienting the hinge 400 properly.

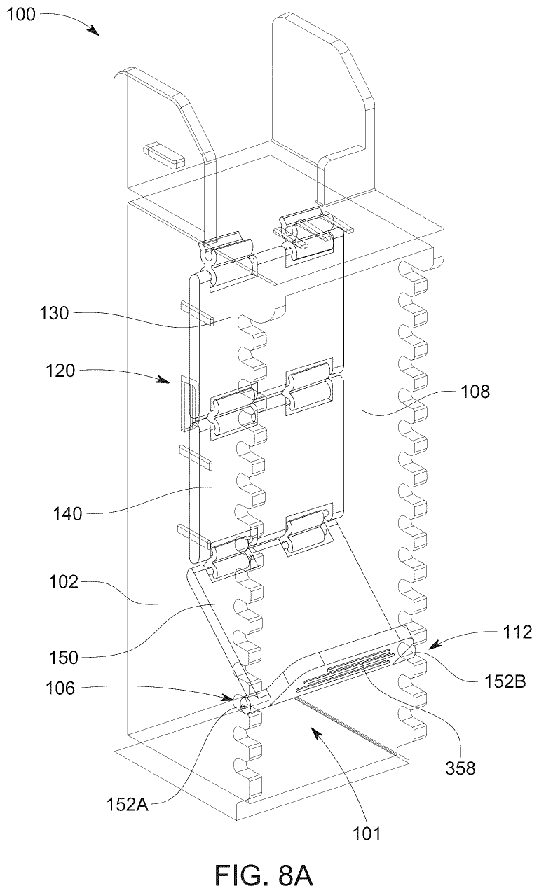

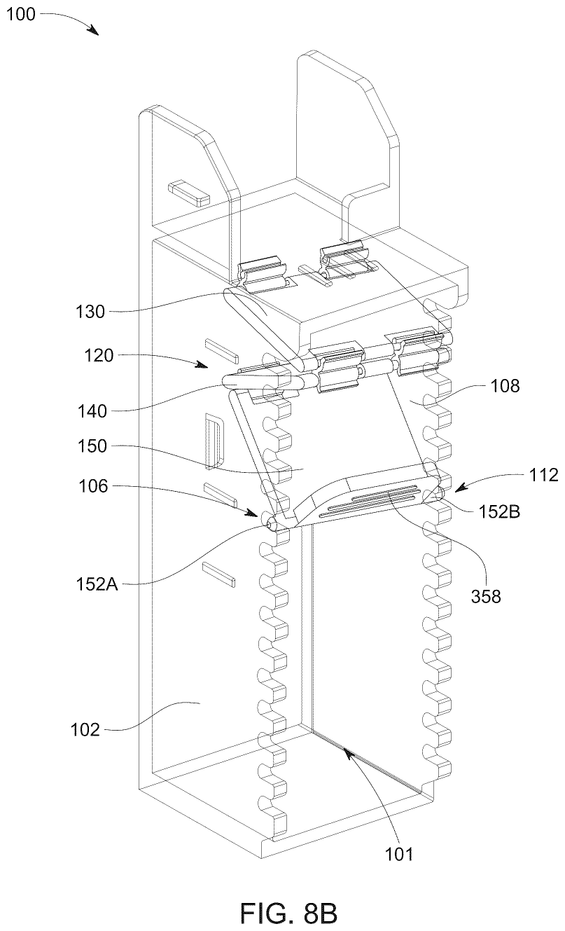

FIG. 5B shows the first screen member 130 and the second screen member 140 when they are fully or substantially folded toward each other. As shown, the central portion 404 of the hinge 400 is long enough so that the screen members 130 and 140 are ably to fully rotate in their respective circular directions 504A and 514A. The folding direction of first screen member 130 and the second screen member 140 is defined generally as the direction that is perpendicular to the first screen member 130 and the second screen member 140 when they are unfolded (FIG. 8A), and parallel to the first screen member 130 and the second screen member 140 when they are fully folded (FIG. 8B). The folding direction thus points away from the side of the hinge 400 that includes the two stopping flanges 408A and 408B and toward the side of the hinge 400 that does not include the stopping flanges 408A and 408B.

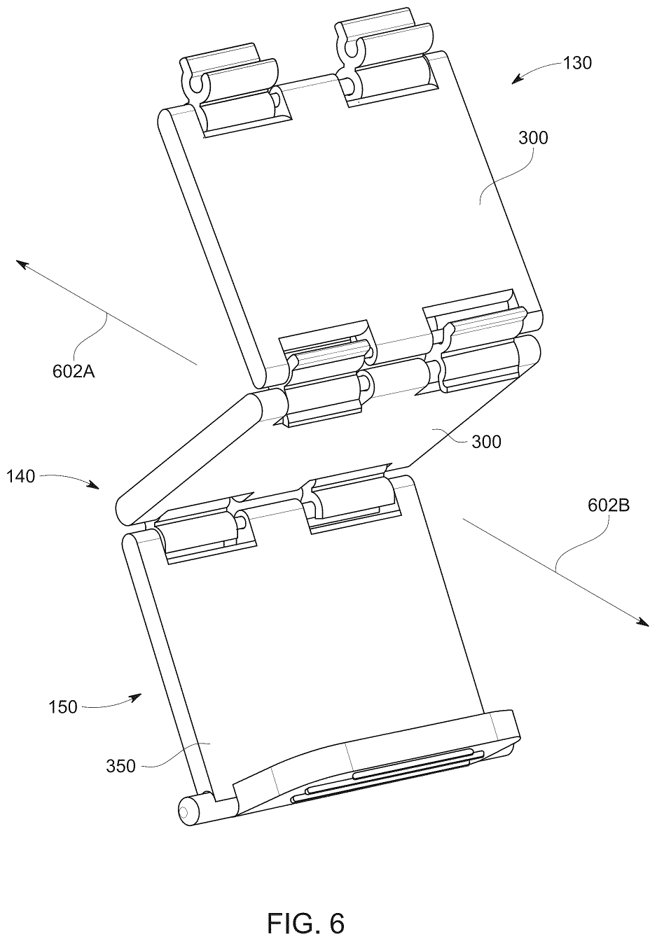

FIG. 6 illustrates the screen 120 when the screen members 130-150 are all connected together and are folded slightly. The pair of hinges 400 connecting the screen members 130 and 140 are oriented so that the stopping flanges 408A and 408B of those hinges 400 are positioned rightward relative to the plane of the figures, so that the folding direction 602A of the screen members 130 and 140 points leftward relative to the plane of the figure. Thus, when the screen members 130 and 140 are folded (or have begun to fold), the folding direction 602A points away from the pair of hinges 400 connecting the screen members 130 and 140. The pair of hinges 400 connecting the screen members 140 and 150 are oriented so that the stopping flanges 408A and 408B of those hinges are positioned leftward relative to the plane of the figures, so that the folding directions 602B of the screen members 140 and 150 point rightward relative to the plane of the figure. Thus, when the screen members 140 and 150 are folded (or have begun to fold), the folding direction 602B points away from the pair of hinges 400 connecting the screen members 140 and 150, and is generally opposite from the folding direction 602A. Notably, the screen member that is coupled to another portion of the anti-reflow device 100 also has a folding direction. In the illustrated implementation, this screen member is the first screen member 130, which has a folding direction that is generally the same as folding direction 602B.

By alternating the direction of the hinges 400 (e.g., the side to which the stopping flanges 408A and 408B extend) that couple the screen members 130-150 together and to the rest of the anti-reflow device 100, when the screen 120 is fully folded the screen members 130-150 will generally be folded on top of each other. Thus, the cross-section of the screen 120 will not be any larger than the area of the body 300 of the screen members 130 and 140 and/or the body 350 of the third screen member 150. In general, for a screen 120 that includes at least three screen members, the direction of the hinges 400 alternates for each adjacent pair of screen members, such that the folding direction of the two screen members within each adjacent pair of screen members will alternate for every pair of screen members.

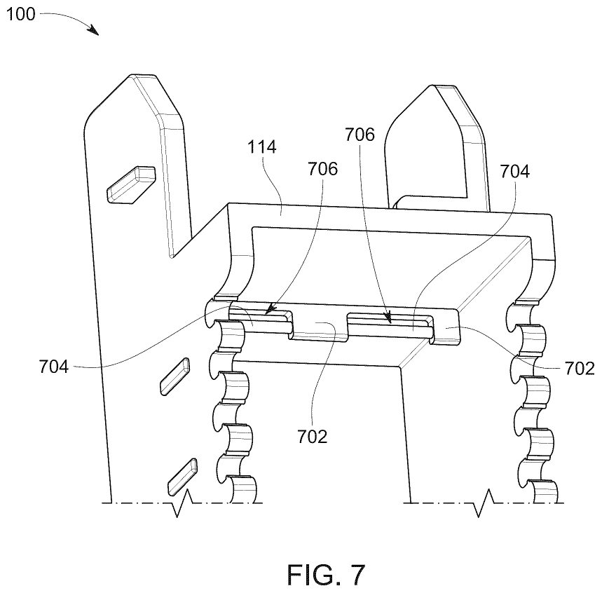

As shown in FIG. 6, the screen 120 includes a pair of hinges 400 connected to the upper edge of the first screen member 130, opposite the edge of the first screen member 130 that is connected to the second screen member 140. These upper hinges 400 can be coupled to the top plate 114 of the anti-reflow device. FIG. 7 shows the underside of the top plate 114 without the screen 120 attached. As shown, the top plate 114 includes tabs 702 extending downward from the surface of the top plate 114, with a pair of rods 704 extending between the tabs 702. The upper pair of hinges 400 are coupled to these rods 704 to thereby pivotally couple the first screen member 130 to the top plate 114. Gaps 706 are defined between the rods 704 and the underside of the top plate 114. The gaps 706 are shorter than the length of the stopping flanges 408A and 408B. Thus, similar to the other hinges 400, these upper hinges 400 can be coupled to the rods 704 in a specific orientation to set the desired folding direction of the first screen member 130.

FIGS. 8A and 8B show transparent views of the anti-reflow device 100 that illustrate how the screen 120 moves. In FIG. 8A, the screen 120 is extended to a first position, and the size of the opening 101 is relatively small. Screen members 130 and 140 are unfolded, while second screen member 150 has folded slightly. The hinges 400 connecting second screen member 140 and screen member 150 are oriented so that the tab 358 of the third screen member 150 pivots toward the slots 106 of the first wall 102, and the slots 112 of the second wall 108. Pin 152A of the third screen member 150 is inserted into a slot 106 of the first wall 102 that is nearer to the second end 103B of the first wall 102 than the first end 103A. Similarly, pin 152B of the third screen member 150 is inserted into a slot 112 of the second wall 108 that is nearer to the second end 109B of the second wall 108 than the first end 103A. When the screen 120 is extended to its longest length (which may be the length illustrated in FIG. 8A or a different length), the position of the screen 120 may be referred to as the fully extended position, the fully unfolded position, the fully closed position, or the fully lengthened position.

In FIG. 8B, the screen 120 has been moved to a second position so that the first screen member 130, the second screen member 140, and the third screen member 150 have begun to fold onto themselves due to the pivotal coupling between them. In general, a user can move the screen 120 upward by grasping the tab 358 of the third screen member 150 and lifting the third screen member 150 to the desired position. The screen 120 will generally fold onto itself as the third screen member 150 is lifted. As shown, the orientation of the hinges 400 alternates between (i) the pair of hinges 400 coupling the first screen member 130 to the top plate 114, (ii) the pair of hinges 400 coupling the first screen member 130 to the second screen member 140, and (iii) the pair of hinges 400 coupling the second screen member 140 to the third screen member 150. Thus, while the first screen member 130 folds toward the front edges of the first wall 102 and the second wall 108, the second screen member 140 folds in the opposite direction, underneath the first screen member 130. The third screen member 150 folds in the opposite direction as the second screen member 140 and thus folds underneath the second screen member 140. Because the second screen member 140 itself has folded underneath the first screen member 130, the third screen member 150 also folds underneath the first screen member 130.

Pin 152A of the third screen member 150 is inserted into a slot 106 of the first wall 102 that is nearer to the first end 103A of the first wall 102 than the second end 103B. Similarly, pin 152B is inserted into a slot 112 of the second wall 108 that is nearer to the first end 109A of the second wall 108 than the second end 109B. While the upper edge of the first screen member 130 stays in generally the same position relative to the top plate 114 and the bottom plate 116, the second screen member 140 and the third screen member 150 are both moved toward the top plate 114 and away from the bottom plate 116, thereby increasing the size of the opening 101. When the screen 120 is retracted to its shortest length (which may be the length illustrated in FIG. 8B or a different length), the position of the screen 120 may be referred to as the fully retracted position, the fully folded position, the fully open position, or the fully shortened position.

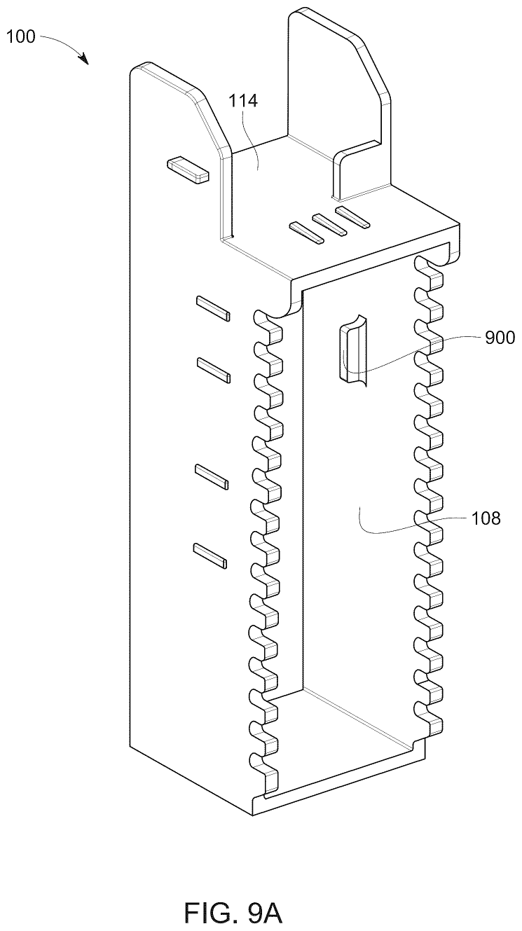

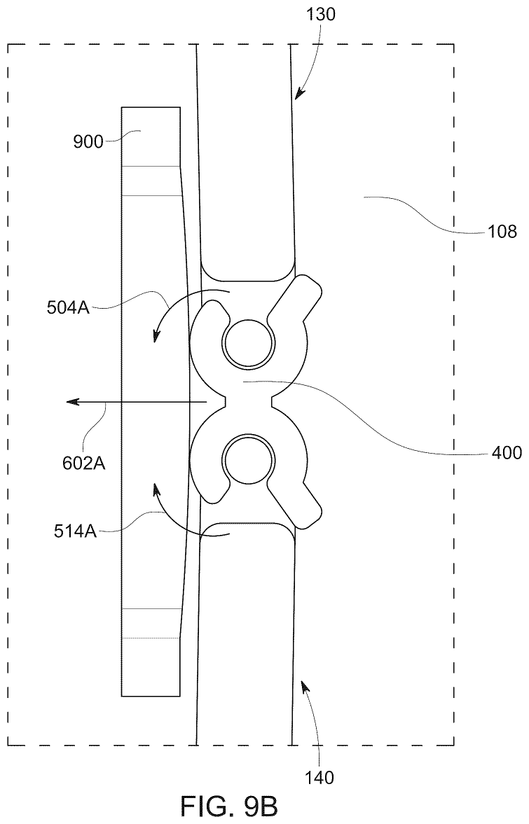

FIG. 9A shows the anti-reflow device without the screen 120 coupled to the top plate 114. As shown, the second wall 108 may include an inwardly projecting tab 900 (also referred to as a biasing tab) that extends from the second wall 108 toward the first wall 102. FIG. 9B shows a side view of the tab 900 when the screen 120 is coupled to the top plate 114. As shown, the tab 900 is positioned so that the hinges 400 coupling the first screen member 130 and the second screen member 140 are aligned with the tab 900. The tab 900 presses against these hinges 400 to cause them to bulge outward away from the tab 900. The tab 900 thus causes the first screen member 130 and the second screen member 140 to be rotated in their respective first circular directions 504A and 514A relative to the hinges 400, such that the pair of screen members 130 and 140 begins to fold slightly in the folding direction 602A. Because the pair of screen members 130 and 140 has already begun to fold in the folding direction 602A, when a user begins to move the screen 120 upward (for example by moving the third screen member 150 upward), the pair of screen members 130 and 140 continues to fold in the folding direction 602A. The tab 900 thus biases the screen members 130 and 140 toward the proper folding direction, which in turn biases each pair of screen members of the screen 120 toward its proper folding direction and ensures that the screen 120 will fold properly.

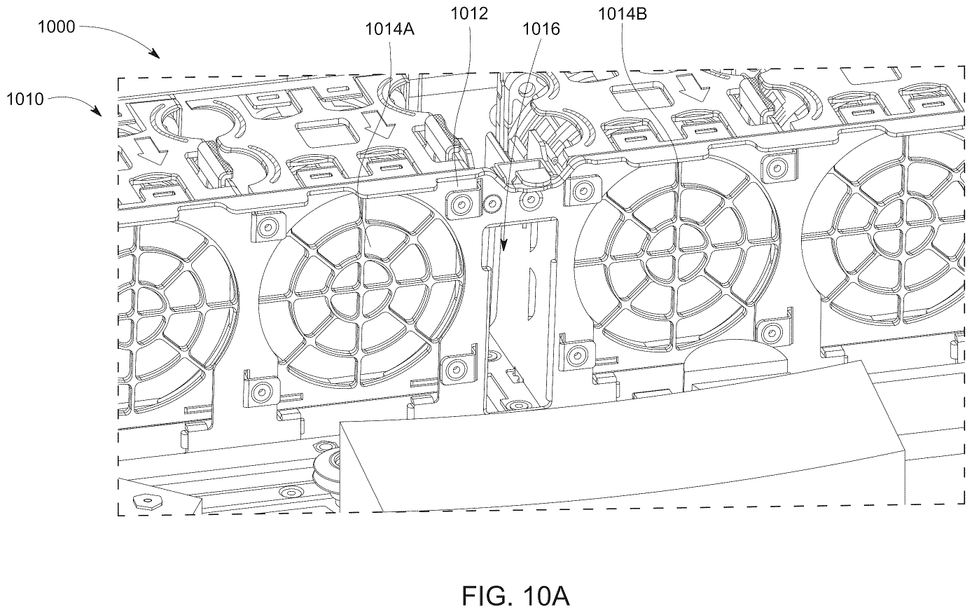

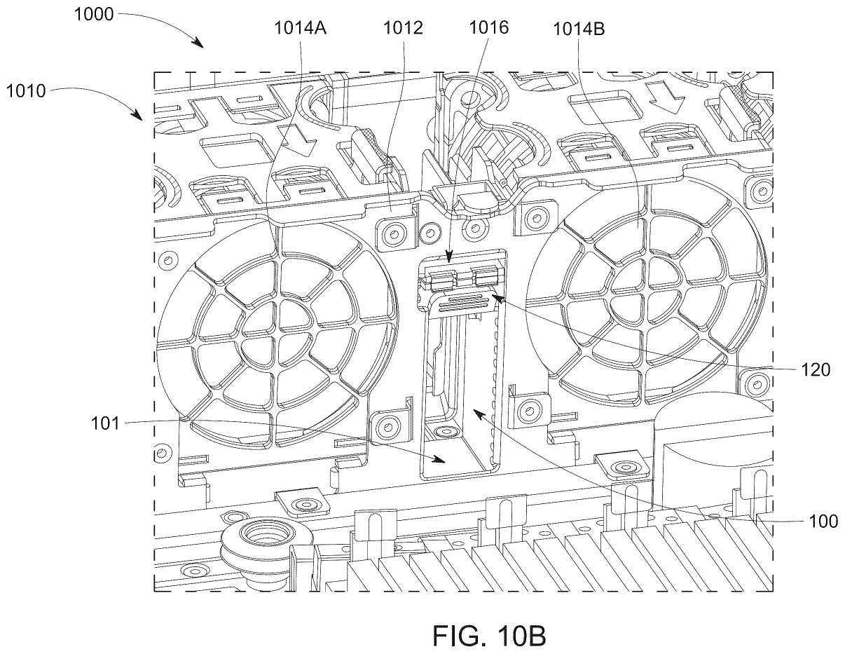

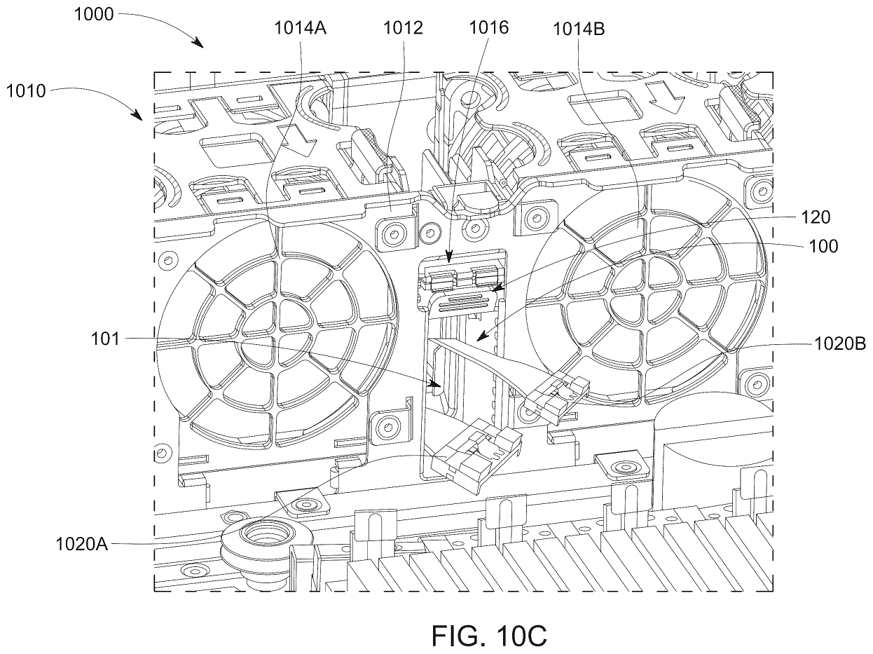

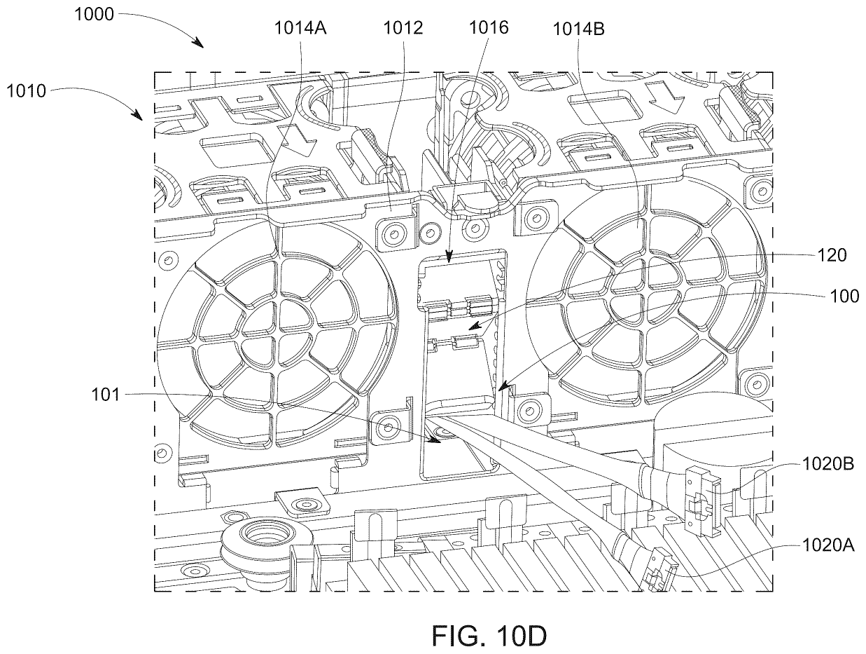

FIGS. 10A-10D show the process of installing the anti-reflow device 100 in a computing device 1000. As shown, the computing device 1000 includes a fan wall 1010 that includes a fan wall housing 1012 and a plurality of fan modules mounted in the fan wall housing 1012. The computing device 1000 will generally also include one or more electronic components, such as mother boards, processors, memory cards, hard drives, etc. These fan modules include at least a first fan module 1014A and a second fan module 1014B. The fan wall also includes an opening 1016 that is defined in the fan wall housing 1012 between the first fan module 1014A and the second fan module 1014B through which various cables of the computing device 1000 may be routed. However, if the cables do not occupy a substantial portion of the opening 1016, the total area of open space between the first fan module 1014A and the second fan module 1014B (which will be a large portion of the total area of the opening 1016) through which air can flow backwards will be larger than desirable, which reduces the cooling achieved by the fan wall 1010.

In FIG. 10B, the anti-reflow device 100 has been installed in the computing device 1000. In the illustrated implementation, the anti-reflow device has been coupled to the fan wall housing 1012. As discussed above with respect to FIG. 1, in some implementations, the anti-reflow device 100 includes any combination of protrusions 118A extending from the first wall 102, protrusions 118B extending from the top plate 114, and protrusions extending from the second wall 108. These protrusions may clip into openings in the fan wall housing 1012 (and/or to other components of the computing device 1000). These protrusions aid in securing the anti-reflow device 100 in place, and prevent the anti-reflow device 100 from inadvertently being dislodged or otherwise moved during use.

In FIG. 10B, the screen 120 has been moved upward as much as possible to the fully folded position, so that the opening 101 of the anti-reflow device 100 is as large as possible. When the screen 120 is in this position, the opening 101 of the anti-reflow device generally overlaps with at least a large portion of the opening 1016 of the fan wall 1010.

In FIG. 10C, cables 1020A and 1020B have been inserted through the opening 101 of the anti-reflow device 100 and the opening 1016 of the fan wall 1010. Because the screen 120 remains in the fully opened position, a large portion of the opening 101 is unoccupied by the cables 1020A and 1020B. Thus, the total area of open space between the first fan module 1014A and the second fan module 1014B (which is a large portion of the total rea of the opening 101) through which air can flow backwards remains larger than desirable.

In FIG. 10D, the screen 120 has been moved downward as much as possible toward the fully unfolded position (and in some cases to the fully unfolded position). Pin 152A of the third screen member 150 has been inserted into a slot 106 of the first wall 102, and pin 152B of the third screen member 150 has been inserted into a corresponding slot 112 of the second wall 108, to thereby lock the screen 120 in place. In this position, the opening 101 of the anti-reflow device 100 is much smaller than in FIG. 10C, such that the cables 1020A and 1020B occupy a large portion of the opening 101. The total area of open space between the first fan module 1014A and the second fan module 1014B through which air can flow backwards is substantially reduced compared to FIG. 10C. The amount of re-flow (e.g., air flowing backwards through the fan wall 1010) is thus reduced, improving the cooling performance of the fan wall 1010.

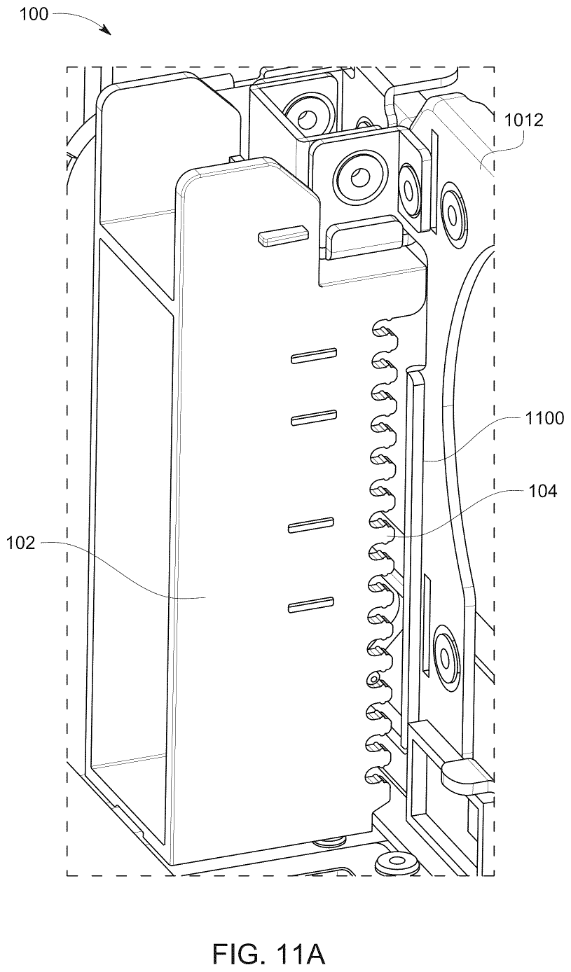

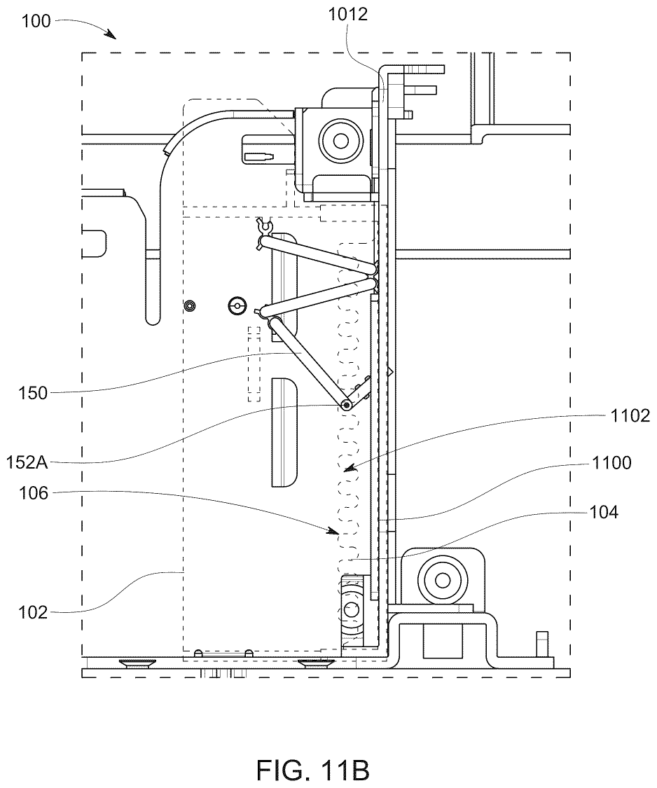

FIG. 11A shows a view of the back side of the fan wall housing 1012 when the anti-reflow device 100 is in position. The computing device 1000 will generally include other structures that surround the anti-reflow device 100 (e.g., the first fan module 1014A and/or the second fan module 1014B, other portions of the fan wall housing 1012, etc.), but these structures are not shown in FIG. 11A. As can be seen, the fan wall housing 1012 is positioned so that the teeth 104 of the first wall 102 are positioned in close proximity to a ridge 1100 of the fan wall housing 1012. The pins 152A and 152B of the third screen member 150 are positioned between the teeth 104 of the first wall 102, and the ridge 1100. The ridge 1100 is positioned so that it is generally directly on the other side of the pin 152A from the first wall 102. The ridge 1100 will thus contact the pin 152A as the pin 152A moves away from the first wall 102 and prevent further movement of the pin 152A away from the first wall 102. While not shown, the fan wall housing 1012 will generally include a corresponding ridge that is positioned opposite the second wall 108 of the anti-reflow device 100 such that the pin 152B is positioned between the second wall 108 and this other ridge.

FIG. 11B is a side view of the computing device 1000 showing the position of the pin 152A of the third screen member 150. As can be seen, a channel 1102 is defined between (i) the teeth 104 of the first wall 102 and (ii) the ridge 1100 of the fan wall housing 1012. The pin 152A of the third screen member 150 is restricted to movement within this channel 1102, as well as into and out of the slots 106 defined in the first wall 102. A corresponding channel will also be defined between (i) the teeth 110 of the second wall 108 and (ii) the other ridge that is positioned in front of the second wall 108. The pin 152B of the third screen member 150 will be restricted to movement within this channel, as well as into and out of the slots 112 defined in the second wall 108. Thus, the ridge 1100 and the corresponding ridge will provide a limited space in which the pins 152A and 152B can move, which reduces the risk that the screen 120 may be damaged during use.

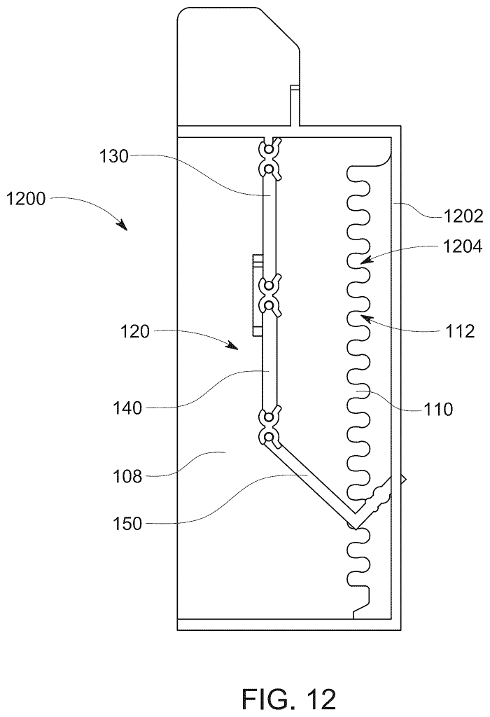

FIG. 12 shows an alternative implementation where the anti-reflow device defines the channels in which the pins 152A and 152B move, instead of the fan wall housing 1012. FIG. 12 shows an anti-reflow device 1200. Anti-reflow device 1200 is substantially the same as anti-reflow device 100, and includes the first wall 102 (not shown in FIG. 12), the second wall 108, and the screen 120 formed from the first screen member 130, the second screen member 140, and the third screen member 150. However, the second wall 108 includes an additional vertical structure 1202 that extends past the teeth 110 and the slots 112 defined therebetween, such that a channel 1204 is defined in the second wall 108 that is continuous with the slots 112. The pin 152B of the third screen member 150 is movable within the channel 1204, as well as into and out of the slots 112, so that the pin 152B is restricted in generally the same manner as the implementation illustrated in FIG. 11A and FIG. 11B. In general, the first wall 102 of the anti-reflow device 1200 will also include an additional vertical structure that extends past the teeth 104 and the slots 106 defined therebetween, such that a channel is defined in the first wall 102 that is continuous with the slots 106, and so that the pin 152A is also restricted in the same manner as the pin 152B.

While the screen 120 of the anti-reflow device 100 and the anti-reflow device 1200 includes only three screen members 130, 140, and 150, the screen 120 may include generally any number of individual screen members. In generally all implementations, the folding direction of every pair of screen members will alternate for each adjacent pair of screen members. In some cases, the folding direction also alternates between (i) an initial screen member that is pivotally coupled to the rest of the anti-reflow device itself (e.g., to the top plate 114) and (ii) the pair of screen members that includes that initial screen member and the next screen member. In these cases, the initial screen member is only able to pivot in one circular direction relative to the top plate 114. In other cases, the initial screen members that is coupled to the top plate 114 or other portion of the anti-reflow device is able to pivot in either direction relative to the top plate 114.

While the anti-reflow device 100 and the anti-reflow device 1200 are both illustrated as having two walls, a top plate, and a bottom plate, other implementations may include more or less structure. For example, an anti-reflow device according to the present disclosure may include only the two walls and the top plate, with no bottom plate. In another example, an anti-reflow device according to the present disclosure does not have a top plate or a bottom plate, and the two walls are coupled to the fan wall housing 1012 and/or to a housing of the computing device itself. In a further example, an anti-reflow device according to the present disclosure may only include one of the walls instead of both, or may include more than two walls.

Further, while the screen 120 is shown as being coupled to the top plate 114, the screen 120 could be coupled to any suitable portion of the anti-reflow device.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing device comprising:
one or more fan modules; and
an anti-reflow device for preventing air reflow from the one or more fan modules, the anti-reflow device being positioned adjacent to at least one of the one or more fan modules, the anti-reflow device including:
a first wall;
a second wall positioned opposite and generally parallel to the first wall such that an opening is defined between the first wall and the second wall; and
a screen positioned within the opening defined between the first wall and the second wall, the screen being movable to adjust a size of the opening.

2. The computing device of claim 1, wherein the screen has a first end coupled adjacent to a first end of the first wall and a first end of the second wall, and a second opposing end that is movable relative to an opposing second end of the first wall and an opposing second end of the second wall.

3. The computing device of claim 2, wherein the first end of the screen is coupled to (i) the first end of the first wall, (ii) the first end of the second wall, (iii) a top plate extending between the first end of the first wall and the first end of the second wall, (iv) or any combination of (i)-(iii).

4. The computing device of claim 3, wherein the second end of the screen moves relative to the second end of the first wall and the second end of the second wall to adjust the size of the opening.

5. The computing device of claim 1, wherein the screen is formed from a plurality of screen members pivotally coupled together, each of the plurality of screen members extending between the first wall and the second wall.

6. The computing device of claim 5, wherein the plurality of screen members are configured to fold onto each other as the screen is moved such that a size of the screen decreases as the size of the opening increases.

7. The computing device of claim 6, wherein the plurality of screen members are pivotally coupled such that a folding direction of two adjacent screen members alternates for every adjacent pair of the plurality of screen members.

8. The computing device of claim 7, wherein the plurality of screen members includes a first screen member, a second screen member pivotally coupled at one end to the first screen member, and a third screen member pivotally coupled to an opposing end of the second screen member.

9. The computing device of claim 8, wherein a first folding direction of the first screen member and the second screen member extends from the pivotal coupling between the first screen member and the second screen member in a first direction, and wherein a second folding direction of the second screen member and the third screen member extends from the pivotal coupling between the second screen member and the third screen member in a second direction that is perpendicular to and opposite the first direction.

10. The computing device of claim 9, wherein the anti-reflow device further includes a rib that presses against the first screen member and the second screen member to bias the first screen member and the second screen member toward the first folding direction.

11. The computing device of claim 5, wherein each pair of screen members of the plurality of screen members is pivotally coupled via at least one hinge that allows each of the pair of screen members to pivot in one circular direction but not in an opposite circular direction.

12. The computing device of claim 11, wherein the at least one hinge that pivotally couples each pair of screen members includes at least one stopping flange that prevents each of the pair of screen members from pivoting in the opposite circular direction.

13. The computing device of claim 12, wherein an orientation of the at least one hinge that couples each pair of screen members alternates for each adjacent pair of screen members.

14. The computing device of claim 1, wherein the screen includes a latch that mates with one or both of the first wall and the second wall to lock the screen and the size of the opening.

15. The computing device of claim 14, wherein the first wall includes a plurality of slots defined therein extending along a length of the first wall, and wherein the latch includes a pin extending from the screen toward the first wall, the pin being selectively insertable into one of the plurality of slots to lock the screen and the size of the opening.

16. The computing device of claim 15, wherein the first wall includes at least one detent extending into at least one slot of the plurality of slots, the detent of the at least one slot resisting movement of the pin out of the at least one slot when the pin is inserted into the at least one slot.

17. The computing device of claim 15, wherein the first wall includes a channel defined therein that is continuous with each of the plurality of slots, and wherein the pin is movable only within the channel, into the plurality of slots, and out of the plurality of slots.

18. The computing device of claim 15, wherein the one or more fan modules are coupled to a fan wall housing, and wherein a portion of the fan wall housing is positioned adjacent to the screen opposite the first wall of the anti-reflow device such that movement of the pin of the anti-reflow device is restricted by the first wall of the anti-reflow device and the portion of the fan wall.

19. A computing device comprising:
one or more electronic components;
a fan wall including at least a first fan module, a second fan module, and an opening defined between the first fan module and the second fan module;
one or more cables; and
an anti-reflow device mounted at least partially in the opening defined between the first fan module and the second fan module, the anti-reflow device including:
a first wall;
a second wall positioned opposite and generally parallel to the first wall such that an opening is defined between the first wall and the second wall, the opening of the anti-reflow device overlapping at least partially with the opening of the fan wall; and
a screen positioned within the opening defined between the first wall and the second wall, the screen being movable relative to the first wall and the second wall,
wherein the one or more cables extend through the opening in the fan wall and the opening in the anti-reflow device, and
wherein the screen is movable to adjust a size of the opening of the anti-reflow device to accommodate a size of the one or more cables extending therethrough.

20. The computing device of claim 19, wherein the screen is formed from a plurality of pivotally coupled screen members configured to fold onto each other as the screen is moved to decrease a size of the opening of the anti-reflow device, and wherein a folding direction of each pair of screen members alternates for every adjacent pair of screen members.
